(19) United States
(12) Patent Application Publication
(10) Pub. No.: US 2015/0200243 A1
(43) Pub. Date: Jul. 16, 2015

(54) METHOD FOR FABRICATING ELECTRONIC DEVICE

(71) Applicant: Sumitomo Electric Device Innovations, Inc., Yokohama-shi (JP)

(72) Inventor: Yasunori NONAKA, Yokohama-shi (JP)

(21) Appl. No.: 14/595,996

(22) Filed: Jan. 13, 2015

(30) Foreign Application Priority Data
Jan. 14, 2014 (JP) 2014-004537

(51) Int. Cl. H01L 49/02; H01L 21/283

(52) U.S. Cl. CPC H01L 28/65; H01L 21/283

(57) ABSTRACT

A method for fabricating an electronic device is provided, and the method comprises the steps of: forming a lower electrode on a substrate; forming a dielectric film on the lower electrode; forming an upper electrode on the dielectric film, the upper electrode including gold (Au); forming a refractory metal layer on at least one of upper or lower surface of the upper electrode, the refractory metal layer having a melting temperature higher than a melting temperature of the upper electrode; forming an insulating film to cover the lower electrode, the dielectric film, the upper electrode, and the refractory metal layer; and dry-etching the insulating film to form an opening therein, the upper electrode or the refractory metal layer being exposed at the opening.

### BACKGROUND OF THE INVENTION

1. Field of the Invention

The present invention relates to a method for fabricating an electronic device in which a dielectric film is provided between an upper electrode and a lower electrode.

2. Related Background Art

Regarding an integrated capacitor included in a semiconductor device, it is known that a capacitor includes a lower electrode, a dielectric film, and an upper electrode, which are formed in this order on a substrate. Japanese Patent Application Laid-open No. 2003-110023 discloses a capacitor, which is formed as follows: an insulating film with an opening located on the lower electrode is formed and then the dielectric film and the upper electrode are formed in the opening.

Japanese Patent Application Laid-open No. 2010-80780 discloses a capacitor, which is formed as follows: an opening is formed in an insulating film which covers a lower electrode, a dielectric film and an upper electrode that are formed on a substrate; and a wiring layer is formed in the opening and the wiring layer is electrically connected with the upper electrode.

### SUMMARY OF THE INVENTION

The wiring layer electrically connected to the upper electrode is obtained in the method that includes: forming an insulating film that covers a lower electrode, a dielectric film, and an upper electrode; then etching the insulating film on the upper electrode to form an opening therein; and forming the wiring layer in the opening.

In this method, gaps are formed between clusters created in the upper electrode by recrystallization occurring at a temperature raised in order to form the insulating film thereon, and in the process of etching the insulating film, the dielectric film is also etched through the gaps, and a conductive material for the wiring layer is also grown in gaps in the dielectric film as well as the gaps in the upper electrode, thereby causing degradation of a breakdown voltage and short circuiting between the upper electrode and the lower electrode.

It is an object for one aspect of the present invention to provide a method for fabricating an electronic device, and the method can prevent degradation of a breakdown voltage and short circuiting from occurring between the upper electrode and the lower electrode of the electronic device.

One aspect of the present invention, relates to a method for fabricating an electronic device. The method comprises the steps of: forming a lower electrode on a substrate; forming a dielectric film on the lower electrode; forming an upper electrode on the dielectric film, the upper electrode including gold (Au); forming a refractory metal layer on at least one of upper or lower surface of the upper electrode, the refractory metal layer having a melting temperature higher than a melting temperature of the upper electrode; forming an insulating film after the upper electrode and the refractory metal layer are formed; forming an opening to the insulating film, the upper electrode or the refractory metal layer being exposed at the opening; and forming a wiring layer electrically connected with the upper electrode via the opening.

### BRIEF DESCRIPTION OF THE DRAWINGS

FIG. 1 is a cross-sectional view of a capacitor according to a first embodiment of the present invention.

FIG. 2A is a cross-sectional view showing a step in a method for fabricating the capacitor according to the first embodiment.

FIG. 2B is a cross-sectional view showing a step in the method according to the first embodiment.

FIG. 2C is a cross-sectional view showing a step in the method according to the first embodiment.

FIG. 2D is a cross-sectional view showing a step in the method according to the first embodiment.

FIG. 2E is a cross-sectional view showing a step in the method according to the first embodiment.

FIG. 2F is a cross-sectional view showing a step in the method according to the first embodiment.

FIG. 2G is a cross-sectional view showing a step in the method according to the first embodiment.

FIG. 3A is a cross-sectional view showing a step in a method for fabricating a capacitor according to a first comparative example.

FIG. 3B is a cross-sectional view showing a step in the method according to the first comparative example.

FIG. 3C is a cross-sectional view showing a step in the method according to the first comparative example.

FIG. 3D is a cross-sectional view showing a step in the method according to the first comparative example.

FIG. 4 is a cross-sectional view showing a capacitor according to a second embodiment of the present invention.

FIG. 5 is a cross-sectional view showing a capacitor according to a third embodiment of the present invention.

### DESCRIPTION OF THE PREFERRED EMBODIMENTS

An embodiment according to the above aspect is directed to a method for fabricating an electronic device, and the method comprises the steps of: forming a lower electrode on a substrate; forming a dielectric film on the lower electrode; forming an upper electrode on the dielectric film, the upper electrode including gold (Au); forming a refractory metal layer on at least one of upper or lower surface of the upper electrode, the refractory metal layer having a melting temperature higher than a melting temperature of the upper electrode; forming an insulating film after the upper electrode and the refractory metal layer were formed; forming an opening in the insulating film, the upper electrode or the refractory metal layer being exposed at the opening; and forming a wiring layer electrically connected with the upper electrode via the opening.

In the method according to the above embodiment, the refractory metal layer is made of a conductive material. In the method according to the above embodiment, an area of a surface of the upper electrode is more than 25 μm².

In the method according to the above embodiment, a growth temperature of the insulating film more than 250 degrees Celsius. In the method according to the above embodiment, a thickness of the upper electrode is less than 300 nm. The method according to the above aspect further comprises the step of performing a heat treatment more than 250 degrees Celsius after formation of the insulating film.

The method according to the above embodiment further comprises the steps of: forming a wiring base layer so as to extend from an inside of the opening on a surface of the upper electrode or the refractory metal layer to a surface of the insulating film; and forming the wiring layer on the wiring base layer. In the method according to the above embodiment, the refractory metal layer includes any one of Ti, Pt, Ta, Mo, and W. In the method according to the above embodiment, the refractory metal layer is formed entirely on the at least one of the upper or lower surfaces of the upper electrode.

In the method according to the above embodiment, the refractory metal layer is formed to cover upper and side surfaces of the upper electrode. In the method according to the above embodiment, the refractory metal layer is formed prior to forming the upper electrode. In the method according to the above embodiment, the refractory metal layer is formed after forming the upper electrode.

An embodiment according to the another aspect of the present invention is directed to a method for fabricating an electronic device, and the method comprises the steps of: forming a lower electrode on a substrate; forming a dielectric film on the lower electrode; forming an upper electrode on the dielectric film, the upper electrode including gold (Au); forming a refractory metal layer on at least one of upper or lower surface of the upper electrode, the refractory metal layer having a melting temperature higher than a melting temperature of the upper electrode; forming an insulating film to cover the lower electrode, the dielectric film, the upper electrode, and the refractory metal layer; and dry-etching the insulating film to form an opening therein, the upper electrode or the refractory metal layer being exposed at the opening. The method of the above aspect may further comprises the steps of: forming a wiring base layer so as to extend from an inside of the opening on a surface of the upper electrode or the refractory metal layer to a surface of the insulating film; and forming a wiring layer on the wiring base layer. In the method according to the above aspect, the refractory metal layer may include any one of Ti, Pt, Ta, Mo, and W. In the method according to the above aspect, the refractory metal layer may be formed entirely on at least one of the upper and lower surfaces of the upper electrode. In the method according to the above aspect, the refractory metal layer may be formed to cover upper and side surfaces of the upper electrode.

Specific examples of a method for fabricating an electronic device according to embodiments of the present invention will be described below with reference to the drawings. The present invention is not limited to the specific examples described below.

### First Embodiment

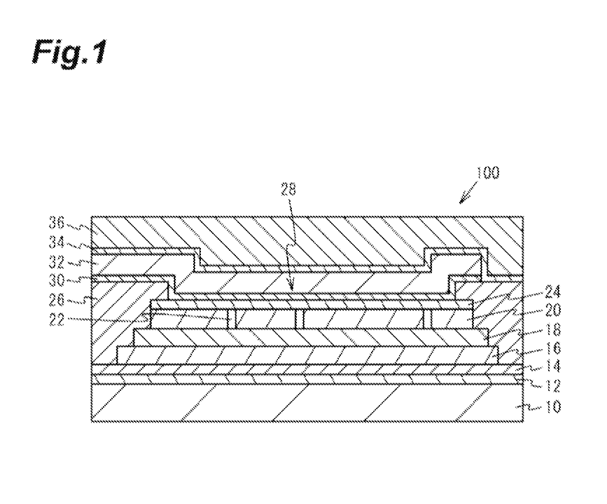

FIG. 1 is a cross-sectional view showing a capacitor according to the first embodiment. As shown in FIG. 1, in a capacitor 100 according to the first embodiment, a GaAs based semiconductor layer 12 is formed on a substrate 10, for example, a GaAs substrate. The GaAs based semiconductor can be a group III-V semiconductor including gallium (Ga) and arsenic (As) as constituents. Specific examples of the GaAs based semiconductor are as follows: GaAs semiconductor, AlGaAs semiconductor, and AlGalnAs semiconductor. For example, the GaAs based semiconductor layer 12 includes a GaAs channel layer and an AlGaAs electron supply layer, which constitute a high electron mobility transistor (HEMT).

A first insulating film 14 is disposed on the GaAs based semiconductor layer 12, and is made of, for example, a silicon nitride film with a thickness of 200 nm. A lower electrode 16 is disposed on the first insulating film 14, and is made of a metal film, which comprises, for example, gold (Au) with a thickness of 200 nm. A dielectric film 18 is formed on the lower electrode 16, and is made of, for example, a silicon nitride film with a thickness of 250 nm.

An upper electrode 20 is disposed on the dielectric film. 18, and is made of a metal film comprising, for example, gold (Au) with a thickness of 300 nm. The upper electrode 20 includes one or more gaps 22, each of which is formed between clusters formed by crystallization. For example, an opening size of one or more gaps among the gaps 22 is not larger than, for example, 1 μm. For example, some or all of the gaps 22 extend through the upper electrode 20, i.e., from the upper surface to the lower surface of the upper electrode 20. A refractory metal layer 24 is disposed on the upper surface of the upper electrode 20. The melting temperature of the refractory metal layer is higher than that of the upper electrode 20. For example, the refractory metal layer 24 is made of a metal film including titanium (Ti) with a thickness of 50 nm, and is provided on the entire upper surface of the upper electrode 20 to cover it. The refractory metal layer 24 includes no gaps formed between clusters therein.

A second insulating film 26 is disposed to cover the lower electrode 16, the dielectric film 18, the upper electrode 20, and the refractory metal layer 24. For example, the second insulating film 26 includes a polyimide film with a thickness of 1.4 μm. An opening 28 is formed in second insulating film 26 located on the refractory metal layer 24. A wiring base layer 30 is formed to extend over the second insulating film 26 and the refractory metal layer 24 that is exposed at the opening 28 of the second insulating film 26. For example, the wiring base layer 30 is made of a metal film including a titanium (Ti) layer with a thickness of 300 μm and a gold (Au) layer with a thickness of 200 nm, which are stacked on the refractory metal layer 24 in this order to form the wiring base layer 30. In another example, the wiring base layer 30 may include at least one of platinum (Pt), tantalum (Ta), molybdenum (Mo), tungsten (W) or titanium (Ti). A wiring layer 32 is disposed on the wiring base layer 30, and is made of, for example, a gold plating layer with a thickness of 1.0 μm. Thus, the wiring base layer 30 functions as, for example, a seed layer for electroplating applied to form the wiring layer 32.

A third insulating film 34 is disposed to cover the wiring layer 32. A fourth insulating film 36 is disposed on the third insulating film 34. The third insulating film 34 is made of, for example, a silicon nitride film with a thickness of 200 μm. The fourth insulating film 34 is made of, for example, a polyimide film with a thickness of 2.0 μm.

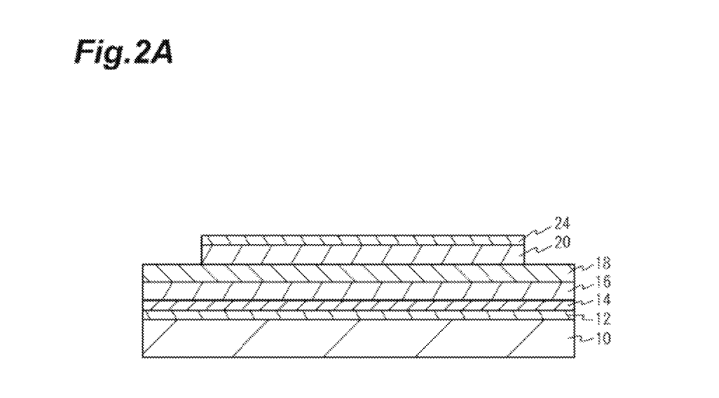

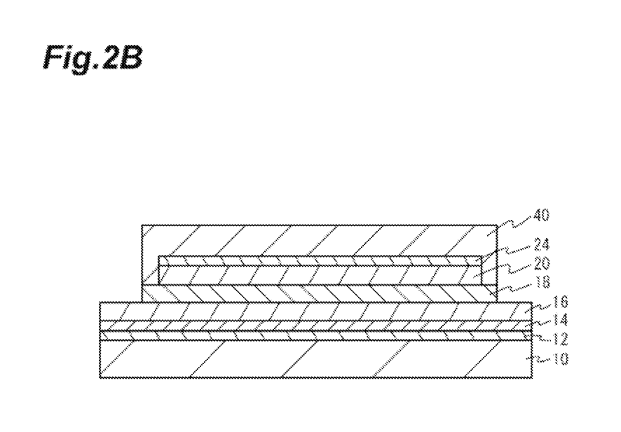

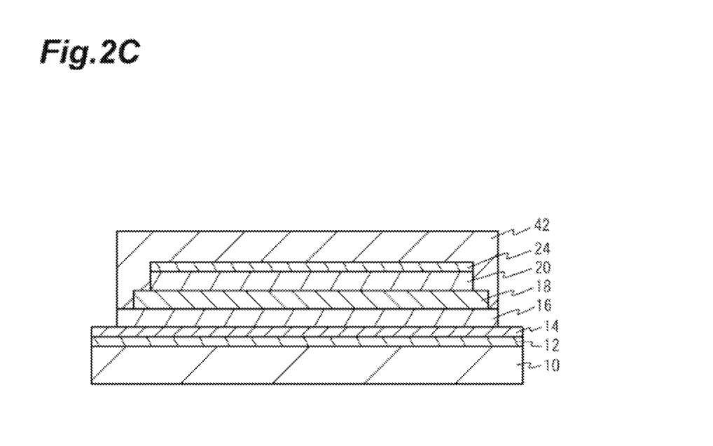

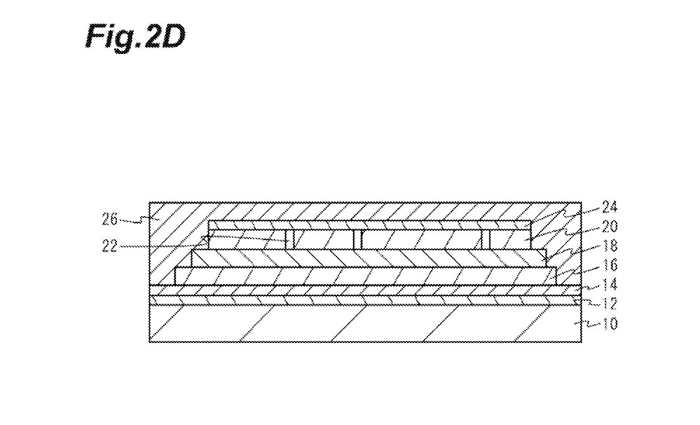

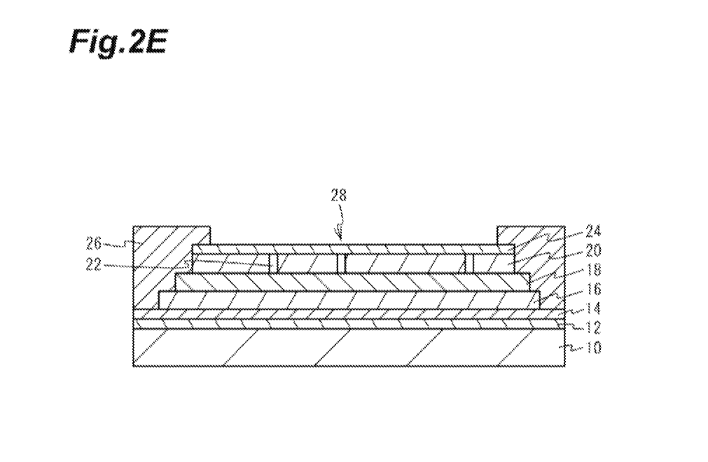

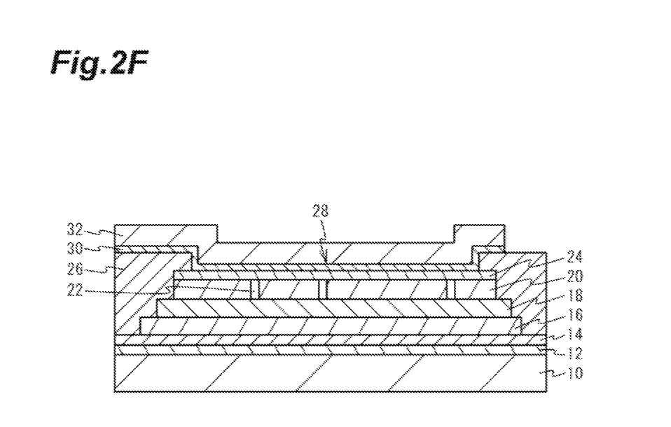

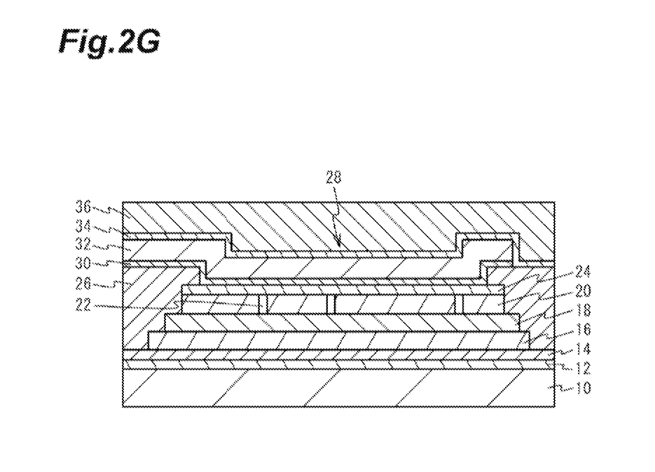

Next, a method for fabricating the capacitor according to the first embodiment will be described. FIGS. 2A to 2G are cross-sectional views showing steps in the method for fabricating the capacitor according to the first embodiment. As shown in FIG. 2A, the GaAs based semiconductor layer 12 is grown on the substrate 10 such as a GaAs substrate by, for example, metal-organic chemical vapor deposition (MOCVD). The first insulating film 14, such as a silicon nitride film, is formed on the GaAs based semiconductor layer 12 by, for example, chemical vapor deposition (CVD). The lower electrode 16, such as a metal film including gold (Au), is formed on the first insulating film 14 by, for example, sputtering. The dielectric film 18, such as a silicon nitride film, is formed on the lower electrode 16 by, for example, CVD. The upper electrode 20 with a desired pattern, such as a metal film including gold (Au), and the refractory metal layer 24, such as a metal film including Ti, are formed on the dielectric film 18, for example, by vapor deposition and liftoff process. The upper electrode 20, such as a metal film including gold (Au), may be formed by sputtering.

As shown in FIG. 2B, the dielectric film 18 is etched using a mask layer 40, which covers the upper electrode 20 and the refractory metal layer 24, as a mask to form the patterned dielectric film 18 with a desired shape.

As shown in FIG. 2C, the lower electrode 16 is etched using a mask layer 42, which covers the upper electrode 20, the refractory metal layer 24 and the dielectric film 18, as a mask to form the patterned lower electrode 16 with a desired shape.

As shown in FIG. 2D, resin for a polyimide film is applied by, for example, spin coating to form the applied resin, for example, the second insulating film 26, which covers the lower electrode 16, the dielectric film 18, the upper electrode 20 and the refractory metal layer 24. Then, the applied film, such as the second insulating film 26, is cured under the condition of, for example, 350 degrees Celsius and 1.5 hours to form the cured resin film. The upper electrode 20, such as the metal film including gold (Au), is recrystallized in the heat treatment of the above temperature to form clusters therein, so that gaps 22 are formed between the clusters by the crystallization in the above process. Some of the gaps 22 extend through the upper electrode 20 to reach the dielectric film 18, and others do not reach it. The refractory metal layer 24 comprises a metal film with a melting temperature higher than that of the upper electrode 20 (for example, a metal film with a melting temperature higher than 1064 degrees Celsius which is the same as a melting temperature of gold, Au). The refractory metal with the higher melting temperature prevents the recrystallization from occurring therein, whereby gaps between the clusters are less likely to be formed in the refractory metal.

As shown in FIG. 2E, the second insulating film 26 is dry-etched using, for example, gas containing fluorine to remove the second insulating film 26 located on the refractory metal layer 24, thereby forming an opening 28 at which the refractory metal layer 24 is exposed. Since no gap is included in the refractory metal layer 24 disposed on the upper electrode 20, the refractory metal layer 24 prevents the dielectric film 18 under the upper electrode 20 from being etched in this process.

As shown in FIG. 2F, the wiring base layer 30 is formed by, for example, vapor deposition and liftoff process, and extends over the second insulating film 26 and the refractory metal layer 24 in the opening 28. On the wiring base layer 30, the wiring layer 32, such as the gold plating layer, is formed by, for example, plating.

As shown in FIG. 2G, the third insulating film 34, such as the silicon nitride film, is formed by, for example, CVD so as to cover the wiring layer 32. Then, resin material for the fourth insulating film 36, such as a polyimide film, is applied to the third insulating film 34 by, for example, spin coating, and the applied polyimide film, is cured. The capacitor according to the first embodiment is formed through the processes described above.

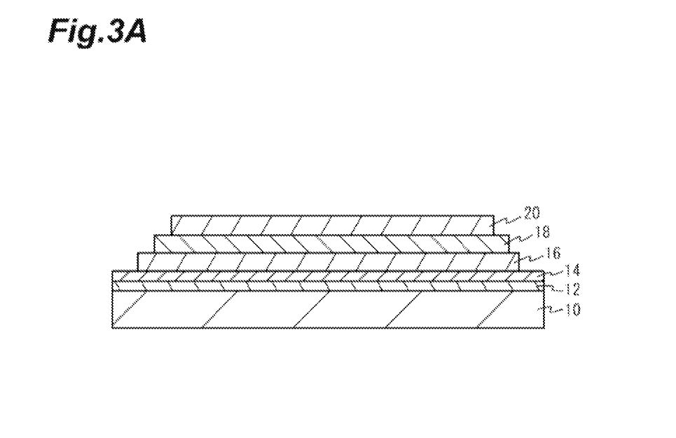

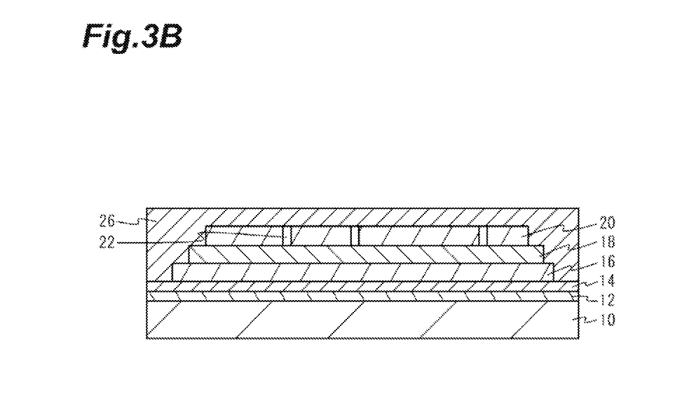

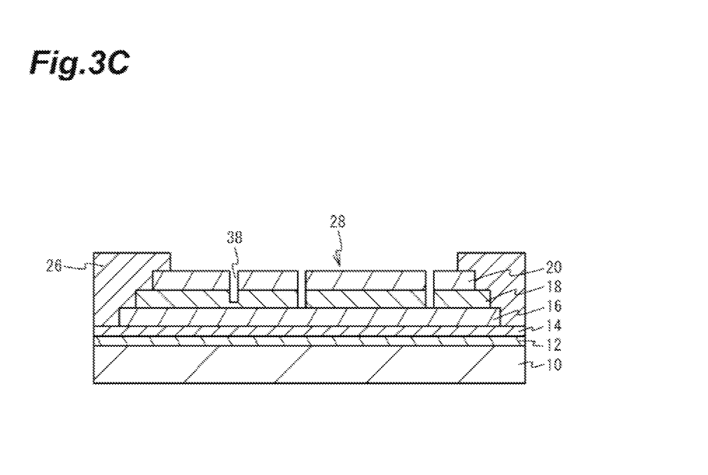

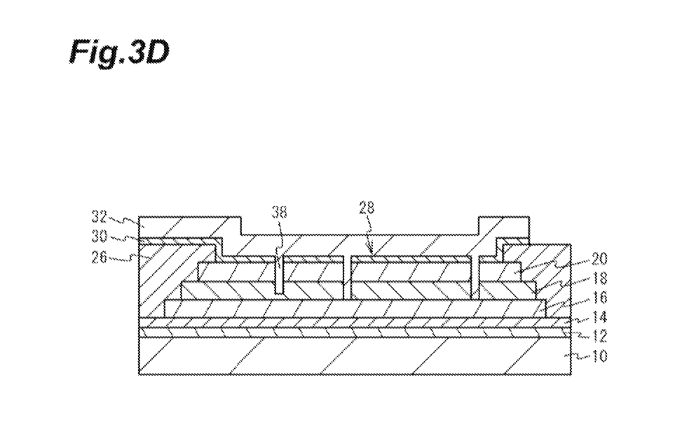

Now, in order to show advantageous effects of the capacitor according to the first embodiment, another capacitor will be described below. FIGS. 3A to 3D are cross-sectional views showing a method for fabricating the other capacitor. As shown in FIG. 3A, the GaAs based semiconductor layer 12, the first insulating film 14, the lower electrode 16, the dielectric film 18, and the upper electrode 20 are formed on the substrate 10 by the same manner as described with reference to FIGS. 2A to 2C in the first embodiment.

As shown in FIG. 3B, polyimide for the second insulating film 26 is applied by, for example, spin coating, so as to cover the lower electrode 16, the dielectric film 18, and the upper electrode 20. Then, the applied resin for the second insulating film 26 is cured under the condition of 350 degrees Celsius and 1.5 hours. As described with reference to FIG. 2D in the first embodiment, the upper electrode 20 is recrystallized in the heat treatment because of the treatment temperature to form clusters, and the formation of the clusters creates the gaps 22 therebetween.

As shown in FIG. 3C, the second insulating film 26 is dry-etched using, for example, a fluorine containing gas, to remove the second insulating film 26 located on the upper electrode 20d, thereby forming an opening 28 which extends through the second insulating film 26 to reach the upper electrode. In the process of dry-etching the second insulating film 26, the dielectric film 18 under the upper electrode 20 is unintentionally etched through the gaps 22 contained in the upper electrode 20 because the dielectric film 18 is exposed at the gaps 22 in this etching step. Thus, gaps 38 extending in a direction from the upper electrode 20 to the dielectric film 18 is formed (specifically, gaps formed in the dielectric film 18 are pin holes, but is referred to collectively as “gap 38”). The above process in which the upper electrode 20 acts as a mask in the etching of the dielectric film 18 results in that the dielectric film 18 are thinned in one or more locations thereof and that the upper surface of the lower electrode 16 are exposed in one or more locations.

As shown in FIG. 3D, the wiring base layer 30, extending along the second insulating film 26 and the upper electrode 20 located in the opening 28, is formed by, for example, vapor deposition and liftoff process. On the wiring base layer 30, a wiring layer 32 is formed, for example, by plating. The wiring base layer 30 and the wiring layer 32 are also formed in the gaps 38, some of which extends through the upper electrode 20 and the dielectric film 18 to reach the lower electrode 16 in FIG. 3D. The wiring base layer 30 formed in the gaps 38 is not depicted in FIG. 3D to simplify the figure. Subsequently, the process described with reference to FIG. 2G according to the first embodiment can be applied thereto, so that the capacitor according to the first comparative example is formed.

In the first comparative example, the wiring layer 32 and the like are also formed in the gaps 38 extending in the direction from the upper electrode 20 to the dielectric film 18. The dielectric film 18 becomes thinned at some of the gaps 38 or others of the gaps 38 pass through the dielectric film 18 to reach the upper surface of the lower electrode 16, which is exposed thereat. This structure is likely to cause the degradation of breakdown voltage and the short circuiting between the upper electrode 20 and the lower electrode 16.

In the first embodiment, as shown in FIG. 2A, the refractory metal layer 24, which has a melting temperature higher than that of the upper electrode 20, is formed on the upper surface of the upper electrode 20 including gold (Au). As shown in FIG. 2D, the second insulating film 26 is formed so as to cover the lower electrode 16, the dielectric film 18, the upper electrode 20, and the refractory metal layer 24. Then, as shown in FIG. 2E, the second insulating film 26 is dry-etched to form the opening 28 therein, and the upper surface of the refractory metal layer 24 is exposed at the opening 28. The process at a temperature at which the second insulating film 26 is formed is likely to cause the recrystallization of the upper electrode 20, comprising gold (Au), to form clusters between which the gaps 22 are defined, but is less likely to form gaps in the refractory metal layer 24 even when the gaps 22 is formed in the upper electrode 20. Accordingly, in the process of dry-etching the second insulating film 26, the refractory metal layer 24 can prevent the dielectric film 18 from being etched to form the opening 28 at which the refractory metal layer 24 is exposed, thereby reducing the occurrence of the degradation of the breakdown voltage and the short circuiting between the upper electrode 20 and the lower electrode 16. In the present embodiment, as shown in FIG. 2F, the wiring base layer 30 including refractory metal (including any one of Ti, Pt, Ta, Mo, and W) is formed both on the second insulating film 26 and in the opening 28, which is located on the surface of the refractory metal layer 24, so as to extend from the opening 28 onto the second insulating film 26 and then the wiring layer 32 is formed on the wiring base layer 30. This process can prevent the degradation of the breakdown voltage and the short circuiting from occurring between the upper electrode 20 and the lower electrode 16.

The refractory metal layer 24 preferably includes any one of Ti, Pt, Ta, Mo, and W in order to prevent as much as possible the creation of the gaps between the clusters, which results from the recrystallization that occurs due to the process carried out at the temperature at which the second insulating film 26 is formed. The refractory metal layer 24 is preferably thick in thickness enough to avoid disappearance of the refractory metal layer 24 in the process of etching the second insulating film 26. For example, the thickness of the refractory metal layer 24 is preferably not smaller than 30 nm, more preferably not smaller than 40 nm, and even more preferably not smaller than 50 nm.

In the upper electrode 20, the gaps 22 are likely to be formed between the clusters due to the recrystallization when the temperature at which the second insulating film 26 is formed is not lower than 250 degrees Celsius. The gaps are more likely to be formed when the temperature is not lower than 300 degrees Celsius, and the gaps are even more likely to be formed when the temperature is not lower than 350 degrees Celsius. When the second insulating film 26 includes a polyimide film, the second insulating film 26 is cured at a temperature at about 350 degrees Celsius as described above with reference to FIG. 2D. Since the recrystallization of the upper electrode 20 is likely to form the gaps 22 between the clusters, the refractory metal layer 24 is preferably formed thereon. Also when the second insulating film 26 includes any one of a silicon nitride film and a silicon oxide film and such a film for the second insulating film 26 is formed at a temperature not lower than 250 degrees Celsius, the recrystallization of the upper electrode 20 is likely to form the gaps 22 between the clusters, and thus the refractory metal layer 24 is preferably formed thereon. The highest possible temperature at which the second insulating film 26 is formed is not higher than the melting temperature of the upper electrode 20.

The first embodiment describes, as an example, a metal-insulator-metal (MIM) capacitor, including the lower electrode 16, the dielectric film 18, and the upper electrode 20, which is disposed on the GaAs based semiconductor layer 12. The capacitor may be disposed on a nitride semiconductor layer or a Si semiconductor layer. The nitride semiconductor encompasses a group III-V semiconductor including nitride as a group V constituent. Specific examples of the nitride semiconductor are as follows: GaN, InN, AlN, AlGaN, InGaN, InAlN, and AlInGaN.

### Second Embodiment

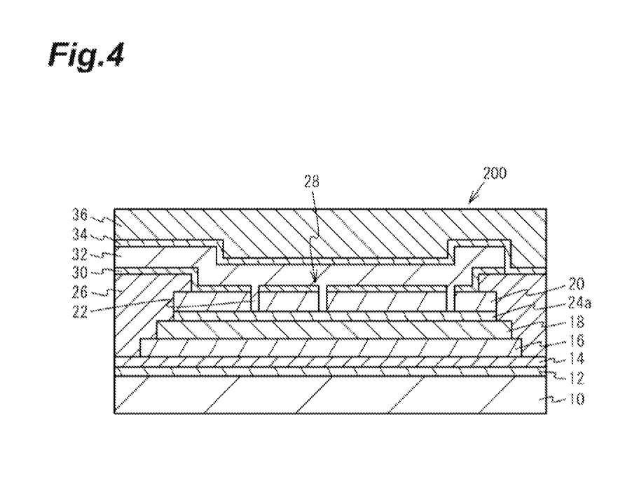

FIG. 4 is a cross-sectional view of a capacitor according to a second embodiment. The wiring base layer 30 and the wiring layer 32 both are formed in the gaps 22. In order to simplify the figure, the wiring base layer 30 in the gap 22 is omitted. As shown in FIG. 4, in a capacitor 200 according to the second embodiment, a refractory metal layer 24a is provided on the lower surface of the upper electrode 20. For example, the refractory metal layer 24a is located on the entire lower surface of the upper electrode 20. As described in the first embodiment, the upper electrode 20 is recrystallized at a temperature at which the second insulating film 26 is formed to form the gaps 22, each of which is formed between the clusters. The second insulating film 26 with the opening 28 is formed on the upper electrode 20. The wiring layer 32 or the like are also formed not only in the opening 28 but also in the gaps 22 located in the upper electrode 20. The remaining items shown in this figure are the same as those in FIG. 1 in the first embodiment, and thus will not be described to avoid, duplication. The capacitor according to the second embodiment can be formed by a method, which is the practically same as that shown in FIG. 2A in the first embodiment method except for the order of the following steps: the step of forming the refractory metal layer 24a and the step of forming the upper electrode 20, and in the method of the second embodiment, the above two steps are arranged in the reverses order.

In the second embodiment, the refractory metal layer on the lower surface of the upper electrode 20 is formed. The refractory metal layer thus formed can also prevent the dielectric film 18 from being etched in the process of forming the opening 28 by dry-etching the second insulating film 26. This can prevent the degradation of the breakdown voltage and the short circuiting from occurring between the upper electrode 20 and the lower electrode 16.

As described in the first and second embodiments, the refractory metal layer, provided on at least one of the upper or lower surface of the upper electrode 20, is effective in preventing the dielectric film 18 from being etched in the process of forming the opening 28, which reaches the upper electrode 20 or the refractory metal layer 24, in the second insulating film 26 by dry-etching. Thus, the degradation of the breakdown voltage and the short circuiting can be prevented from occurring between the upper electrode 20 and the lower electrode 16. In order to avoid etching of the dielectric film 18, the refractory metal layer is preferably formed entirely on at least one of the upper or the lower surface of the upper electrode 20.

### Third Embodiment

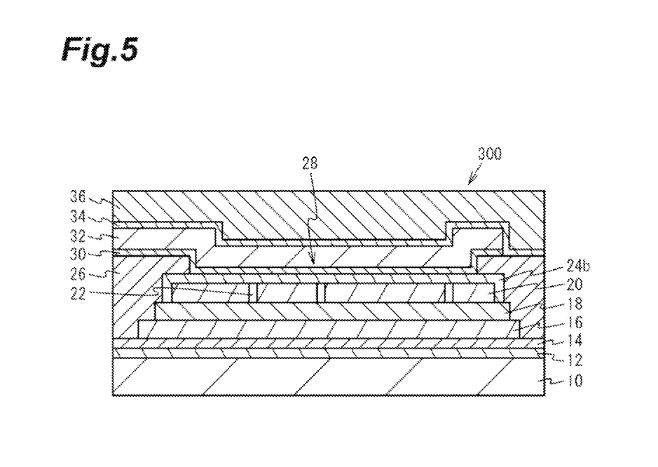

FIG. 5 is a cross-sectional view of a capacitor according to a third embodiment. As shown in FIG. 5, a capacitor 300 according to the third embodiment includes a refractory metal layer 24b, which is formed to cover the upper and side surfaces of the upper electrode 20. The remaining items in the third embodiment are the same as those in FIG. 1 in the first embodiment, and thus will not be described to avoid duplication. The capacitor according to the third embodiment can be fabricated by a method, similar to that in FIG. 2A in the first embodiment, in which the upper electrode 20 and the refractory metal layer 24b are formed in separate steps each of which vapor deposition and liftoff process are carried out using a resist layer as a mask.

In the third embodiment, the refractory metal layer 24b is formed so as to cover the upper and side surfaces of the upper electrode 20, and the refractory metal layer 24b thus formed can prevent the degradation of the breakdown voltage and the short circuiting from occurring between the upper electrode 20 and the lower electrode 16. Furthermore, the third embodiment can also achieve higher moisture resistance.

This embodiment can prevent degradation of a breakdown voltage and short circuiting from occurring between an upper electrode and a lower electrode.

Having described and illustrated the principle, of the invention in a preferred embodiment thereof, it is appreciated by those having skill in the art that the invention can be modified in arrangement and detail without departing from such principles. We therefore claim all modifications and variations coming within the spirit and scope of the following claims.

What is claimed is:

1. A method for fabricating an electronic device, comprising the steps of;
forming a lower electrode on a substrate;
forming a dielectric film on the lower electrode;
forming an upper electrode on the dielectric film, the upper electrode including gold (Au);
forming a refractory metal layer on at least one of upper or lower surface of the upper electrode, the refractory metal layer having a melting temperature higher than a melting temperature of the upper electrode;
forming an insulating film after the upper electrode and the refractory metal layer are formed;
forming an opening to the insulating film, the upper electrode or the refractory metal layer being exposed at the opening; and
forming a wiring layer electrically connected with the upper electrode via the opening.

2. The method according to claim 1, wherein the refractory metal layer is a conductive material.

3. The method according to claim 1, wherein an area of the upper electrode is more than 25 μm².

4. The method according to claim 1, wherein a growth temperature of the insulating film more than 250 degrees Celsius.

5. The method according to claim 1, wherein a thickness of the upper electrode is less than 300 nm.

6. The method according to claim 1, further comprising a step of performing a heat treatment more than 250 degrees Celsius after formation of the insulating film.

7. The method according to claim 1, further comprising the steps of:
forming a wiring base layer so as to extend from an inside of the opening on a surface of the upper electrode or the refractory metal layer to a surface of the insulating film; and
forming the wiring layer on the wiring base layer.

8. The method according to claim 1, wherein the refractory metal layer includes any one of Ti, Pt, Ta, Mo, and W.

9. The method according to claim 1, wherein the refractory metal layer is formed entirely on the at least one of the upper or lower surfaces of the upper electrode.

10. The method according to claim 1, wherein the refractory metal layer is formed to cover upper and side surfaces of the upper electrode.

11. The method according to claim 1, wherein the refractory metal layer is formed prior to forming the upper electrode.

12. The method according to claim 1, wherein the refractory metal layer is formed after forming the upper electrode.
